(19) United States
(12) Patent Application Publication
(10) Pub. No.: US 2018/0294392 A1
(43) Pub. Date: Oct. 11, 2018

(54) COMPOSITE CONDUCIVE TO HEAT DISSIPATION OF LED-MOUNTED SUBSTRATE AND METHOD OF MANUFACTURING THE SAME

(71) Applicant: NATIONAL CHUNG SHAN INSTITUTE OF SCIENCE AND TECHNOLOGY, Taoyuan City (TW)

(72) Inventors: BIING-JYH WENG, Taoyuan City (TW); SHAO-YU WANG, Taoyuan City (TW); HSIN-PING CHANG, New Taipei City (TW); WEI-HSING TUAN, Taipei City (TW); TSUNG-TE CHOU, Taipei City (TW)

(21) Appl. No.: 15/481,162

(22) Filed: Apr. 6, 2017

(51) Int. Cl. H01L 33/64; B32B 7/02; B32B 9/00; B32B 9/04; B32B 37/10; B32B 37/06; C04B 37/02

(52) U.S. Cl. CPC H01L 33/641; C04B 2237/363; B32B 9/007; B32B 9/041; B32B 37/10; B32B 37/06; C01B 31/04; C04B 37/021; H01L 2933/0075; B32B 2250/03; B32B 2307/302; B32B 2309/12; B32B 2310/0418; B32B 2313/04; B32B 2457/14; C01P 2006/32; C04B 2237/32; C04B 2237/40; B32B 7/02

(57) ABSTRACT

A composite conducive to heat dissipation of an LED-mounted substrate includes a ceramic layer being of a thermal conductivity of 20˜24 W/mK; a metal layer being of a thermal conductivity of 100˜200 W/mK; and a graphite layer being of an in-plane thermal conductivity of 950 W/mK and a through-plane thermal conductivity of 3 W/mK, wherein the metal layer is disposed between the ceramic layer and the graphite layer. The composite has one side displaying satisfactory insulation characteristics and the other side displaying satisfactory heat transfer characteristics. The composite incurs low material costs and requires a simple manufacturing process.

### FIELD OF THE INVENTION

The present invention relates to composites and methods of manufacturing the same and, more particularly, to a composite conducive to heat dissipation of LED-mounted substrate and method of manufacturing the same.

### BACKGROUND OF THE INVENTION

With green awareness on the rise worldwide, energy efficiency and power consumption reduction are deemed important, thereby allowing the LED industry to steal the spotlight. LED products have advantages as follows: energy efficient, power saving, highly efficient, short response time, long service life, mercury-free, and environment-friendly. However, only 20˜30% of light generated from conventional LEDs is emitted, and the remaining 70˜80% of light generated is converted into heat. If not dissipated, the heat will heat up the LEDs to the detriment of their service life, light emission efficiency, and operation stability.

Conventional substrates for use with LEDs are made of a composite (Flame Retardant 4, FR4) which consists of fiberglass and epoxy resins. The composite is good at insulation but has a low thermal conductivity (K), i.e., <5 W/mK); as a result, heat generated from LEDs is seldom rapidly transferred to the outside through the substrates, thereby resulting in ongoing accumulation of heat within the substrates and eventually a reduction in the life service of the LEDs mounted on the substrates.

In an attempt to overcome the aforesaid drawback of the conventional substrates for use with LEDs, researchers developed an aluminum nitride (AlN)-containing substrate for use with LEDs, wherein the AIN-containing substrate is good at insulation and heat transfer. However, the manufacturing of the AIN-containing substrate entails performing several manufacturing processes, including cold isostatic pressing (CIP) and sintering, and thus requires sophisticated, pricey equipment and process-related know-how, which is really difficult for general manufacturers to afford and access, respectively.

### SUMMARY OF THE INVENTION

It is an objective of the present invention to provide a material conducive to heat dissipation of an LED-mounted substrate, as the material incurs low costs and requires a simple manufacturing process.

In order to achieve the above and other objectives, the present invention provides a composite conducive to heat dissipation of an LED-mounted substrate. The composite comprises: a ceramic layer of a thermal conductivity of 20˜24 W/mK; a metal layer of a thermal conductivity of 100˜200 W/mK; and a graphite layer of an in-plane thermal conductivity of 950 W/mK and an through-plane thermal conductivity of 3 W/mK, wherein the metal layer is disposed between the ceramic layer and the graphite layer.

In an embodiment of the present invention, the metal layer is of a thermal conductivity of 185 W/mK.

In order to achieve the above and other objectives, the present invention further provides a method of manufacturing a composite conducive to heat dissipation of an LED-mounted substrate, comprising: a stacking step for stacking a ceramic layer, a metal layer, and a graphite layer so that the metal layer is disposed between the ceramic layer and the graphite layer to form a stack structure; a clamping step for fixing the stack structure in place with a clamp; and a heat treatment step for performing a heat treatment process on the stack structure to form the composite conducive to heat dissipation of the LED-mounted substrate, wherein the ceramic layer is of a thermal conductivity of 20˜24 W/mK, the metal layer of a thermal conductivity of 100˜200 W/mK, and the graphite layer of an in-plane thermal conductivity of 950 W/mK and a through-plane thermal conductivity of 3 W/mK.

In an embodiment of the present invention, the stacking step is preceded by a cleaning step for cleaning the ceramic layer, the metal layer, and the graphite layer with an alcohol.

In an embodiment of the present invention, the alcohol is a methanol or an ethanol.

In an embodiment of the present invention, the clamp is made of a material selected from the group consisting of aluminum oxide, zirconium oxide, and graphite.

In an embodiment of the present invention, the clamp exerts a clamping pressure of 0.1˜5.0 kg/cm² on the stack structure.

In an embodiment of the present invention, the heat treatment step further comprises: a placing step for placing in a tube furnace the stack structure fixed in place by the clamp; a gas introducing step for introducing a protective gas into the tube furnace at a flow rate of 20˜200 mL/min; a temperature raising step for raising a temperature in the tube furnace at a temperature raising speed of 1˜10° C./min from a room temperature to 1000˜1500° C. and maintaining the temperature in the tube furnace at 1000˜1500° C. for 10˜120 minutes; and a temperature lowering step for lowering a temperature in the tube furnace at a temperature lowering speed of 1˜10° C./min to the room temperature.

In an embodiment of the present invention, the protective gas is nitrogen or argon.

The present invention is characterized in that two different materials are coupled together by a metal layer disposed therebetween to form a composite. Therefore, the composite has one side displaying satisfactory insulation characteristics and the other side displaying satisfactory heat transfer characteristics. The composite incurs low material costs and requires a simple manufacturing process.

### BRIEF DESCRIPTION OF THE DRAWINGS

Objectives, features, and advantages of the present invention are hereunder illustrated with specific embodiments in conjunction with the accompanying drawings, in which:

FIG. 1 is a schematic view of a composite conducive to heat dissipation of an LED-mounted substrate according to an embodiment of the present invention;

FIG. 2 is a schematic view of the process flow of a method of manufacturing a composite conducive to heat dissipation of an LED-mounted substrate according to an embodiment of the present invention; and

FIG. 3 is a schematic view of the process flow of a heat treatment step according to an embodiment of the present invention.

### DETAILED DESCRIPTION OF THE PREFERRED EMBODIMENTS

The present invention is described below with reference to preferred embodiments of the present invention to enable persons skilled in the art to gain insight into the technical features of the present invention and implement the present invention accordingly. Persons skilled in the art can easily understand the objectives and advantages of the present invention by making reference to the disclosure contained in the specification, the claims, and the drawings. The above embodiments are illustrative of the features and effects of the present invention rather than restrictive of the scope of the substantial technical disclosure of the present invention. Persons skilled in the art may modify and alter the above embodiments without departing from the spirit and scope of the present invention. Therefore, the scope of the protection of rights of the present invention should be defined by the appended claims.

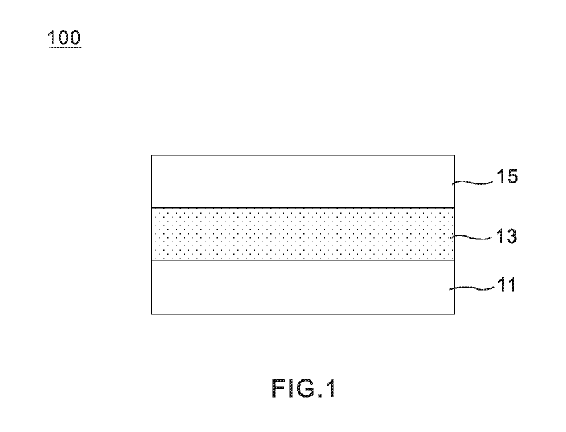

Referring to FIG. 1, there is shown a schematic view of a composite 100 conducive to heat dissipation of an LED-mounted substrate according to an embodiment of the present invention. As shown in FIG. 1, the composite 100 comprises a ceramic layer 11, a metal layer 13, and a graphite layer 15, wherein the metal layer 13 is disposed between the ceramic layer 11 and the graphite layer 15. In the embodiment, the ceramic layer 11 is of a thermal conductivity of 20˜24 W/mK, the metal layer 13 of a thermal conductivity of 100˜200 W/mK, and the graphite layer 15 of an in-plane thermal conductivity of 950 W/mK and a through-plane thermal conductivity of 3 W/mK.

With the graphite layer 15 being made from a stack of flakes of natural graphite, its in-plane and through-plane thermal conductivity differ greatly. By contrast, the ceramic layer 11 and the metal layer 13 each have equal in-plane and through-plane thermal conductivity because they are formed by powder hot pressing.

In the embodiment of the present invention, two different materials, namely the graphite layer 15 and the ceramic layer 11, are combined to jointly display good insulation and a high thermal conductivity. However, the graphite layer 15 and the ceramic layer 11 cannot be directly coupled together. Hence, in the embodiment of the present invention, a third material, i.e., the metal layer 13, which does not compromise the physical properties of the graphite layer 15 and the ceramic layer 11, is used to couple the graphite layer 15 and the ceramic layer 11 together at a specific temperature and atmosphere to form the composite 100 conducive to heat dissipation of an LED-mounted substrate. In addition, the metal layer 13 provides a low interface thermal resistance so that the composite 100 displays satisfactory heat transfer characteristics.

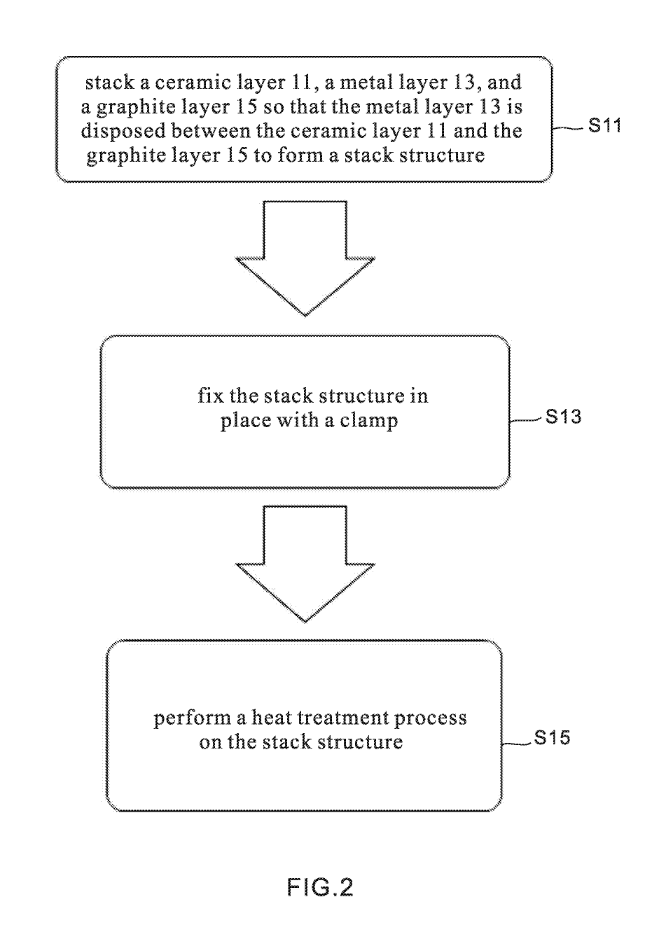

Referring to FIG. 2, there is shown a schematic view of the process flow of a method of manufacturing the composite 100 according to an embodiment of the present invention. The method is hereunder illustrated by the steps depicted with the schematic view of FIG. 2. The method of manufacturing the composite 100 according to an embodiment of the present invention may include any step not shown in the schematic view of FIG. 2. Hence, the present invention is not restrictive of the steps of the process flow of the method illustrated by FIG. 2.

Step S11 is a stacking step for stacking a ceramic layer 11, a metal layer 13, and a graphite layer 15 so that the metal layer 13 is disposed between the ceramic layer 11 and the graphite layer 15 to form a stack structure. In the embodiment, the ceramic layer 11 is of a thermal conductivity of 20˜24 W/mK, the metal layer 13 of a thermal conductivity of 100˜200 W/mK, and the graphite layer 15 of an in-plane thermal conductivity of 950 W/mK and a through-plane thermal conductivity of 3 W/mK.

In a variant embodiment, the stacking step is preceded by a cleaning step. The cleaning step involves cleaning surfaces of the ceramic layer 11, the metal layer 13, and the graphite layer 15 with an alcohol, such as methanol or ethanol.

Step S13 is a clamping step for fixing in place the stack structure formed from the ceramic layer 11, the metal layer 13, and the graphite layer 15 with a clamp. In the embodiment, the clamp must be made of a material which does not react with the stack structure, and the material is exemplified by aluminum oxide, zirconium oxide, and graphite. The clamp exerts a clamping pressure of 0.1˜5.0 kg/cm² on the stack structure. The lower the clamping pressure is, the less satisfactorily are the ceramic layer 11, the metal layer 13, and the graphite layer 15 coupled together. However, an overly high clamping pressure is likely to damage the stack structure.

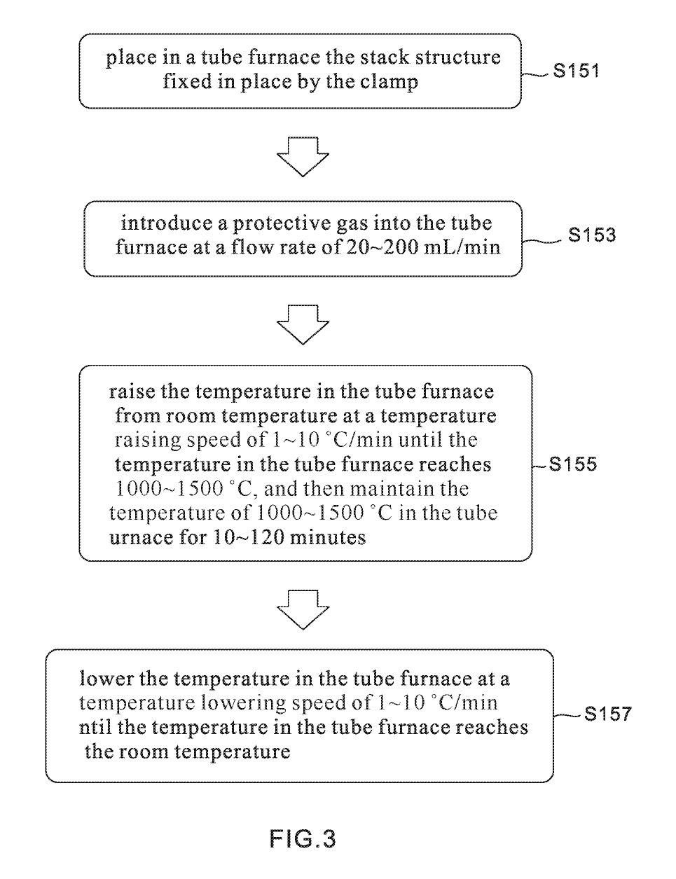

Step S15 is a heat treatment step for performing a heat treatment process on the stack structure formed from the ceramic layer 11, the metal layer 13, and the graphite layer 15, so as to form the composite 100 conducive to heat dissipation of an LED-mounted substrate. The heat treatment step is carried out with, but is not restricted to, the steps illustrated by FIG. 3.

Referring to FIG. 3, there is shown a schematic view of the process flow of a heat treatment step according to an embodiment of the present invention.

Step S151 is a placing step for placing in a tube furnace the stack structure formed from the ceramic layer 11, the metal layer 13, and the graphite layer 15 and fixed in place by the clamp.

Step S153 is a gas introducing step for introducing a protective gas into the tube furnace at a flow rate of 20˜200 mL/min. In an embodiment, the protective gas does not react with the stack structure but contains an inert gas, such as nitrogen or argon.

Step S155 is a temperature raising step for raising the temperature in the tube furnace from room temperature at a temperature raising speed of 1˜10° C./min until the temperature in the tube furnace reaches 1000˜1500° C., and then maintaining the temperature of 1000˜1500° C. in the tube furnace for 10˜120 minutes.

Step S157 is a temperature lowering step for lowering the temperature in the tube furnace at a temperature lowering speed of 1˜10° C./min until the temperature in the tube furnace reaches the room temperature.

In a comparative embodiment, a composite is also manufactured with the steps shown in FIG. 2 and FIG. 3. The comparative embodiment is distinguished from the preceding embodiment in that the metal layer of the composite manufactured in the comparative embodiment has a thermal conductivity of 50˜100 W/mK. Compared with that of the preceding embodiment, the metal layer of the composite manufactured in the comparative embodiment has a lower thermal conductivity and thus less heat is transferred from the ceramic layer to the graphite layer for heat dissipation, thereby compromising the overall heat transfer performance of the composite.

Theoretically speaking, the higher the thermal conductivity of the metal layer 13 in the embodiment of the present invention is, the better it is. However, the manufacturing of a metal layer with a thermal conductivity higher than the thermal conductivity, i.e., 100˜200 W/mK, of the metal layer 13 of the present invention requiring an alloy synthesized by a more complicated manufacturing process which incurs higher costs, thereby ruling out the feasibility of mass production. Hence, the composite 100 of the embodiment of the present invention strikes a balance between heat transfer performance and cost control, thereby being suitable for mass production.

The method of manufacturing a composite conducive to heat dissipation of an LED-mounted substrate according to an embodiment of the present invention is described below.

First, providing a ceramic layer 11, a metal layer 13, and a graphite layer 15, wherein the ceramic layer 11 is of a thermal conductivity of 20˜24 W/mK, the metal layer 13 of a thermal conductivity of 185 W/mK, and the graphite layer 15 of in-plane and through-plane thermal conductivity of 950 W/mK and 3 W/mK, respectively.

Afterward, cleaning surfaces of the ceramic layer 11, the metal layer 13, and the graphite layer 15, stacking the cleaned ceramic layer 11, metal layer 13, and graphite layer 15 to form a stack structure, fixing the stack structure in place with a clamp, and placing the stack structure in a tube furnace.

Afterward, introducing nitrogen into the tube furnace at a flow rate of 50 mL/min, raising the temperature in the tube furnace at a temperature raising speed of 3° C./min from the room temperature to 1050° C., and maintaining the temperature in the tube furnace at 1050° C. for around 15 minutes.

Finally, lowering the temperature in the tube furnace at a temperature lowering speed of 3° C./min until the temperature in the tube furnace reaches the room temperature, and then removing from the tube furnace the stack structure formed from the ceramic layer 11, the metal layer 13, and the graphite layer 15, where the stack structure thus removed is a composite conducive to heat dissipation of an LED-mounted substrate.

A specimen is manufactured from the composite thus manufactured. Measurement of the through-plane thermal conductivity of 20˜24 W/mk of the specimen reveals a three-point bending strength of 331˜407 MPa,

In conclusion, the present invention provides a composite conducive to heat dissipation of an LED-mounted substrate. The composite can be easily manufactured by using the metal layer 13 to couple together the ceramic layer 11 and the graphite layer 15 at a specific temperature and atmosphere without compromising the physical properties of the ceramic layer 11 and the graphite layer 15. The composite thus manufactured displays satisfactory insulation and heat transfer performance. Moreover, the metal layer 13 provides a low interface thermal resistance so that the composite 100 displays satisfactory heat transfer characteristics.

Furthermore, the composite incurs low material costs and does not require any complicated manufacturing process.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A composite conducive to heat dissipation of an LED-mounted substrate, the composite comprising:
a ceramic layer of a thermal conductivity of 20˜24 W/mK;
a metal layer of a thermal conductivity of 100˜200 W/mK; and
a graphite layer of an in-plane thermal conductivity of 950 W/mK and a through-plane thermal conductivity of 3 W/mK,
wherein the metal layer is disposed between the ceramic layer and the graphite layer.

2. The composite of claim 1, wherein the metal layer is of a thermal conductivity of 185 W/mK.

3. A method of manufacturing a composite conducive to heat dissipation of an LED-mounted substrate, comprising:
a stacking step for stacking a ceramic layer, a metal layer, and a graphite layer so that the metal layer is disposed between the ceramic layer and the graphite layer to form a stack structure;
a clamping step for fixing the stack structure in place with a clamp; and
a heat treatment step for performing a heat treatment process on the stack structure to form the composite conducive to heat dissipation of the LED-mounted substrate,
wherein the ceramic layer is of a thermal conductivity of 20˜24 W/mK, the metal layer of a thermal conductivity of 100˜200 W/mK, and the graphite layer of an in-plane thermal conductivity of 950 W/mK and a through-plane thermal conductivity of 3 W/mK.

4. The method of claim 3, wherein the stacking step is preceded by a cleaning step for cleaning the ceramic layer, the metal layer, and the graphite layer with an alcohol.

5. The method of claim 4, wherein the alcohol is one of a methanol and an ethanol.

6. The method of claim 3, wherein the clamp is made of a material selected from the group consisting of aluminum oxide, zirconium oxide, and graphite.

7. The method of claim 3, wherein the clamp exerts a clamping pressure of 0.1˜5.0 kg/cm² on the stack structure.

8. The method of claim 3, wherein the heat treatment step further comprises:
a placing step for placing in a tube furnace the stack structure fixed in place by the clamp;
a gas introducing step for introducing a protective gas into the tube furnace at a flow rate of 20˜200 mL/min;
a temperature raising step for raising a temperature in the tube furnace at a temperature raising speed of 1˜10° C./min from a room temperature to 1000˜1500° C. and maintaining the temperature in the tube furnace at 1000˜1500° C. for 10˜120 minutes; and
a temperature lowering step for lowering a temperature in the tube furnace at a temperature lowering speed of 1˜10° C./min to the room temperature.

9. The method of claim 8, wherein the protective gas is one of nitrogen and argon.
